(19) United States
(12) Patent Application Publication
(10) Pub. No.: US 2007/0164330 A1
(43) Pub. Date: Jul. 19, 2007

(54) DISPLAY SUBSTRATE AND METHOD OF MANUFACTURING THE SAME

(75) Inventors: Chang-Oh Jeong, Suwon-si (KR); Hong-Sick Park, Suwon-si (KR); Shi-Yul Kim, Yongin-si (KR); Sang-Gab Kim, Seoul (KR)

Correspondence Address: CANTOR COLBURN, LLP, 55 GRIFFIN ROAD SOUTH, BLOOMFIELD, CT, 06002, US

(73) Assignee: SAMSUNG ELECTRONICS CO., LTD, Suwon-si (KR)

(21) Appl. No.: 11/566,886

(22) Filed: Dec. 5, 2006

(30) Foreign Application Priority Data
Jan. 16, 2006 (KR) 10-2006-0004472

(51) Int. Cl. H01L 31/113

(52) U.S. Cl. 257/291

(57) ABSTRACT

A display substrate includes a base substrate, a first metal pattern, a gate insulating layer, a second metal pattern, a channel layer and a pixel electrode. The first metal pattern is formed on the base substrate, and includes a gate line and a gate electrode of a switching element. The gate insulating layer is formed on the base substrate including the first metal pattern. The second metal pattern is formed on the gate insulating layer, and includes a source electrode, a drain electrode and a source line. The channel layer is formed under the second metal pattern, and is patterned to have substantially the same side surface as a side surface of the second metal pattern. The pixel electrode is electrically connected to the drain electrode. Therefore, an afterimage on a display panel, thus improving display quality.

The present application claims priority to Korean Patent Application No. 2006-04472, filed on Jan. 16, 2006, and all the benefits accruing therefrom under 35 U.S.C. § 119, the contents of which in its entirety are herein incorporated by reference.

### BACKGROUND OF THE INVENTION

1. Field of the Invention

The present invention relates to a display substrate and a method of manufacturing the display substrate. More particularly, the present invention relates to a display substrate and a method of manufacturing the display substrate, which is capable of decreasing an afterimage.

2. Description of the Related Art

A liquid crystal display (“LCD”) device includes a display substrate, an opposite facing substrate and a liquid crystal layer interposed between the display substrate and the opposite facing substrate. Liquid crystals of the liquid crystal layer have dielectric anisotropy. The liquid crystals vary arrangement in response to an electric field applied thereto, and thus a light transmittance of the liquid crystal layer is changed, thereby displaying an image. When screen size and resolution of the LCD device are increased, the display substrate requires signal lines of low electrical resistance. Thus, a display substrate having an aluminum or aluminum alloy signal line has been devised. However, an adhesive strength between the aluminum and a pixel electrode is small, and the aluminum diffuses into an adjacent silicon layer. Therefore, when a source line and a drain electrode include the aluminum, each source line and drain electrode has a multi-layered structure.

A gate line, the source line and a switching element of the display substrate are formed through a photolithography process. In order to decrease the number of processes, a source metal pattern including the source line, the source electrode and the drain electrode and a channel layer are patterned using substantially the same photo mask. Thus, the channel layer having substantially the same shape as the source metal pattern is formed under the source metal pattern. The source metal pattern is isotropically etched using an etchant, and the channel layer is anisotropically etched through a reactive ion etching (“RIE”) process. A side of the source metal pattern is recessed with respect to a side of an etching mask during the isotropically etching to form an undercut under the etching mask. The channel layer is anisotropically etched in a substantially vertical direction with respect to a surface of the display substrate through the reactive ion etching process so that a width of the active layer is greater than the source metal pattern. Therefore, the active layer protrudes with respect to the side of the source metal pattern. However, when each source line and the drain electrode has the multi-layered structure, an amount of the protrusion of the channel layer is greatly increased thereby causing an afterimage to be displayed on the LCD device.

### BRIEF SUMMARY OF THE INVENTION

The present invention provides a display substrate capable of decreasing display of an afterimage on an LCD device.

The present invention also provides a method of manufacturing the above-mentioned display substrate.

A display substrate in accordance with an exemplary embodiment of the resent invention includes a base substrate, a first metal pattern, a gate insulating layer, a second metal pattern, a channel layer and a pixel electrode. The first metal pattern is formed on the base substrate, and includes a gate line and a gate electrode of a switching element. The gate insulating layer is formed on the base substrate including the first metal pattern. The second metal pattern is formed on the gate insulating layer, and includes a source electrode, a drain electrode and a source line. The channel layer is formed under the second metal pattern, and has substantially a same side surface as a side surface of the second metal pattern. The pixel electrode is electrically connected to the drain electrode.

A method of manufacturing a display substrate in accordance with another exemplary embodiment of the present invention is provided as follows. A source metal layer is formed on a base substrate, on which a first metal pattern, a gate insulating layer and a channel layer are formed, in sequence. The source metal layer includes a first metal layer and a second metal layer. The first metal pattern includes a gate line and a gate electrode. The source metal layer is etched using a photoresist pattern to form a second metal pattern including an electrode pattern and a source line. The second metal pattern is cleaned using a cleaning liquid which selectively etches the second metal layer to etch a side surface of the second metal layer by a predetermined distance. The photoresist pattern is ashed by a predetermined amount so that the photoresist pattern has substantially a same width as a width of the second metal layer. A portion of the first metal layer and the channel layer is dry etched using the photoresist pattern. The portion of the first metal layer and the channel layer protrudes with respect to the second metal layer. The electrode pattern is partially etched to form a switching element including a source electrode, a drain electrode and a channel portion. A passivation layer is formed on the base substrate having the switching element. A pixel electrode electrically connected to the drain electrode is formed.

A method of manufacturing a display substrate in accordance with still another exemplary embodiment of the present invention is provided as follows. A gate insulating layer, an active layer, an ohmic contact layer and a source metal layer are formed on a base substrate on which a first metal pattern is formed. The source metal layer includes a first metal layer and a second metal layer. The first metal pattern includes a gate line and a gate electrode. The source metal layer is patterned using a photoresist pattern to form a second metal pattern including an electrode pattern and a source line. The second metal pattern is cleaned using a cleaning liquid which selectively etches the second metal layer. The photoresist pattern is removed so that the photoresist pattern has substantially a same width as a width of the second metal layer. A portion of the first metal layer, the active layer and the ohmic contact layer is dry etched using the photoresist pattern. The photoresist pattern is removed by a predetermined thickness to expose a portion of the electrode pattern. The exposed portion of the electrode pattern is partially etched to form a source electrode and a drain electrode of the switching element. The ohmic contact layer is etched using the source and drain electrodes as an etching mask to expose a portion of the active layer. A passivation layer partially exposing the drain electrode is formed. A pixel electrode electrically connected to the drain electrode is formed.

According to the present invention, the protrusion of the channel layer is removed to decrease a leakage current induced by light, thereby decreasing an afterimage on a display panel.

### BRIEF DESCRIPTION OF THE DRAWINGS

The above and other aspects, features and advantages of the present invention will become more apparent by describing in more detail exemplary embodiments thereof with reference to the accompanying drawings, in which:

FIG. 1 is a plan view illustrating a display substrate in accordance with an exemplary embodiment of the present invention;

FIG. 2 is a cross-sectional view taken along line I-I′ shown in FIG. 1;

FIGS. 3A to 3K are cross-sectional views illustrating a method of manufacturing the display substrate shown in FIG. 2;

FIG. 4 is a cross-sectional view illustrating a display substrate in accordance with another exemplary embodiment of the present invention; and

FIGS. 5A to 5H are cross-sectional views illustrating a method of manufacturing the display substrate shown in FIG. 4.

### DETAILED DESCRIPTION OF THE INVENTION

The present invention is described more fully hereinafter with reference to the accompanying drawings, in which exemplary embodiments of the present invention are shown. This invention may, however, be embodied in many different forms and should not be construed as limited to the exemplary embodiments set forth herein. Rather, these exemplary embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, exemplary embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be described in more detail with reference to the accompanying drawings.

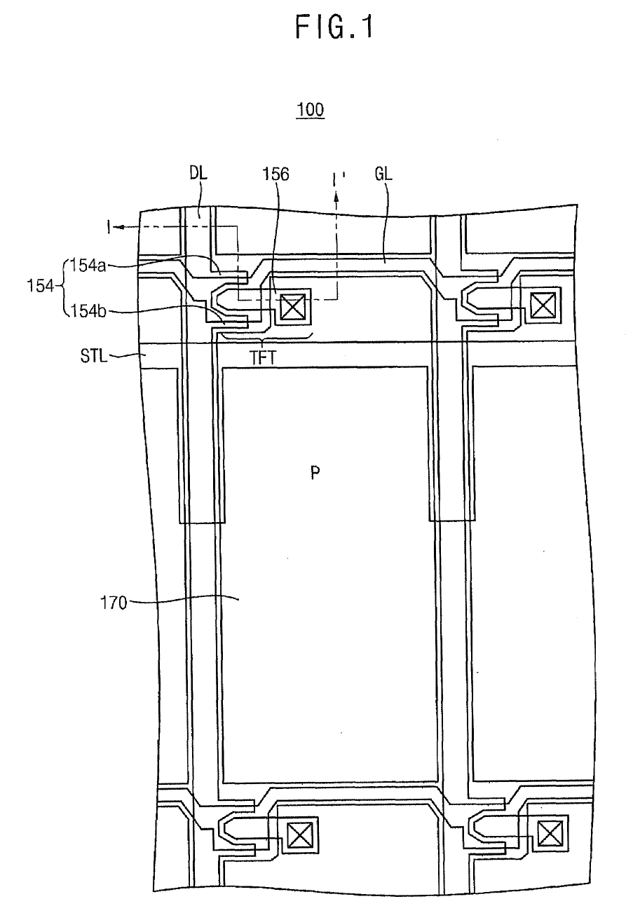

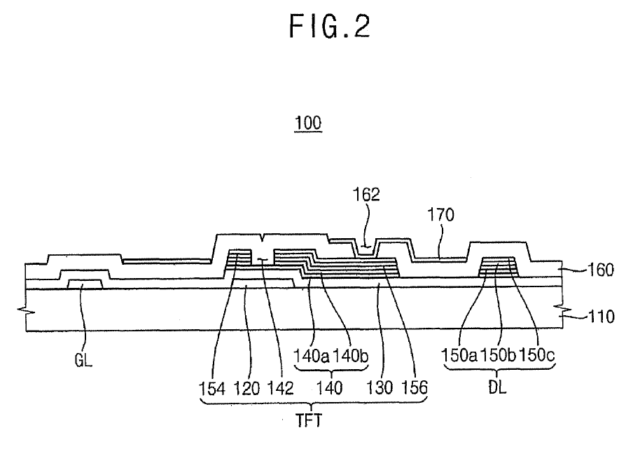

FIG. 1 is a plan view illustrating a display substrate in accordance with an exemplary embodiment of the present invention. FIG. 2 is a cross-sectional view taken along line I-I′ shown in FIG. 1.

Referring to FIGS. 1 and 2, the display substrate 100 includes a base substrate 110, a source line DL, a gate line GL, a storage common line STL, a switching element TFT, a passivation layer 160 and a pixel electrode 170. The display substrate 100 may further include a plurality of source lines DL, a plurality of gate lines GL, a plurality of storage common lines STL, a plurality of switching elements TFT and a plurality of pixel electrodes 170.

The base substrate 110 is formed of a transparent material which transmits light. For example, the base substrate 110 is formed of a glass substrate.

The gate lines GL are extend on the base substrate 110 in a first direction. The data lines DL extend on, the base substrate 110 in a second direction substantially perpendicular to and crossing the first direction. A plurality of pixel parts P defined by pairs of adjacent gate lines GL and data lines DL is formed on the base substrate 110.

The storage common lines STL extend in the first direction, and extend substantially parallel with the gate lines GL. Alternatively, a portion of each source line DL is branched from a remaining portion of each source line DL to form each storage common line STL. The storage common lines STL function as a common electrode of a storage capacitor which maintains a pixel voltage applied to a liquid crystal capacitor.

Each of the switching elements TFT are formed on a respective pixel part P. For example, each of the switching elements TFT includes a gate electrode 120, a gate insulating layer 130, a source electrode 154, a drain electrode 156 and a channel layer 140.

The gate electrode 120 extends from one of the gate lines GL. A first metal pattern includes the gate electrode 120. In addition, the first metal pattern also includes the gate lines GL and the storage common lines STL.

The first metal pattern is formed of a conductive material. Examples of the conductive material which may be used for the first metal pattern include chromium, aluminum, tantalum, molybdenum, titanium, tungsten, copper, silver, but is not limited thereto. These conductive materials may be used alone, in an alloy thereof or in a combination thereof. Alternatively, the first metal pattern may have a multi-layered structure.

The gate insulating layer 130 is formed on the base substrate 110 to cover the first metal pattern. For example, the gate insulating layer 130 includes silicon nitride.

The source electrode 154 extends from one of the source lines DL. The source electrode 154 partially overlaps the gate electrode 120. For example, the source electrode 154 may have a U-shape, and may include a first patterned portion 154a and a second patterned portion 154b (see FIG. 1). The second patterned portion 154b is spaced apart from the first patterned portion 154a. A second metal pattern includes the source electrode 154 and the source lines DL.

The second metal pattern may further include the drain electrode 156. The drain electrode 156 is spaced apart from the first and second patterned portions 154a and 154b of the source electrode 154, and is interposed between the first and second patterned portions 154a and 154b of the source electrode 154.

The second metal pattern may further include the source lines DL, the source electrode 154 and the drain electrode 156. The second metal pattern may have a triple layered structure including a first metal layer 150a, a second metal layer 150b and a third metal layer 150c. For example, the first metal layer 150a may include molybdenum or molybdenum alloy. The second metal layer 150b may include aluminum or aluminum alloy. The third metal layer 150c may include molybdenum or molybdenum alloy.

The first metal layer 150a prevents silicon of the channel layer 140 from diffusing into the second metal layer 150b including aluminum or aluminum alloy. Also, the first metal layer 150a may prevent aluminum of the second metal layer 150b from diffusing into the silicon of the channel layer 140.

The second metal layer 150b functions as a conductive path for an electric signal, and includes aluminum or aluminum alloy having a low resistance.

The third metal layer 150c protects the aluminum or aluminum alloy second metal layer 150b. The third metal layer 150c prevents a hill lock of the second metal layer 150b during subsequent processes performed at a high temperature, and decreases a contact resistance between the second metal pattern and the pixel electrode 170.

The channel layer 140 is formed under the second metal pattern including the source lines DL, the source electrode 154 and the drain electrode 156. The channel layer 140 includes an active layer 140a and an ohmic contact layer 140b. The active layer 140a includes amorphous silicon (“a-Si:H”). The ohmic contact layer 140b includes n+amorphous silicon (“n+a-Si:H”). An upper portion of an amorphous silicon (a-Si:H) layer may include n+impurities implanted thereon at a high concentration to form the ohmic contact layer 140b.

When the channel layer 140 is patterned with the second metal pattern using substantially the same mask, a width of the channel layer 140 may be greater than that of the second metal pattern. However, in FIGS. 1 and 2, a protruding length of the channel layer 140 with respect to the second metal pattern is no more than about 0.5 μm. For example, the channel layer 140 is patterned so that the channel layer 140 and the second metal pattern have substantially the same etching surface.

A channel portion 142, through which the active layer 140a is exposed, is formed on a region between the source electrode 154 and the drain electrode 156.

The passivation layer 160 is formed on the gate insulating layer 130 to cover the second metal pattern. The passivation layer 160 has a contact hole 162 through which the drain electrode 156 is exposed.

The pixel electrode 170 is formed on the passivation layer 160 corresponding to the pixel part P. The pixel voltage is applied from the drain electrode 156 to the pixel electrode 170 through the contact hole 162. The pixel electrode 170 is formed of a transparent conductive material which transmits light. Examples of the transparent conductive material which may be used for the pixel electrode 170 include indium tin oxide (“ITO”), indium zinc oxide (“IZO”), but is not limited thereto.

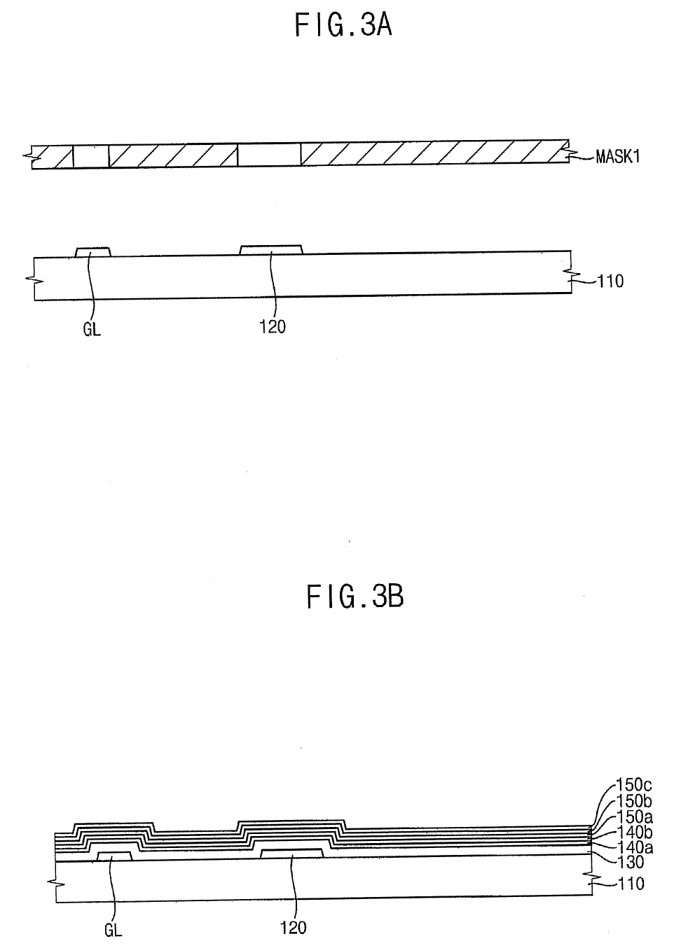

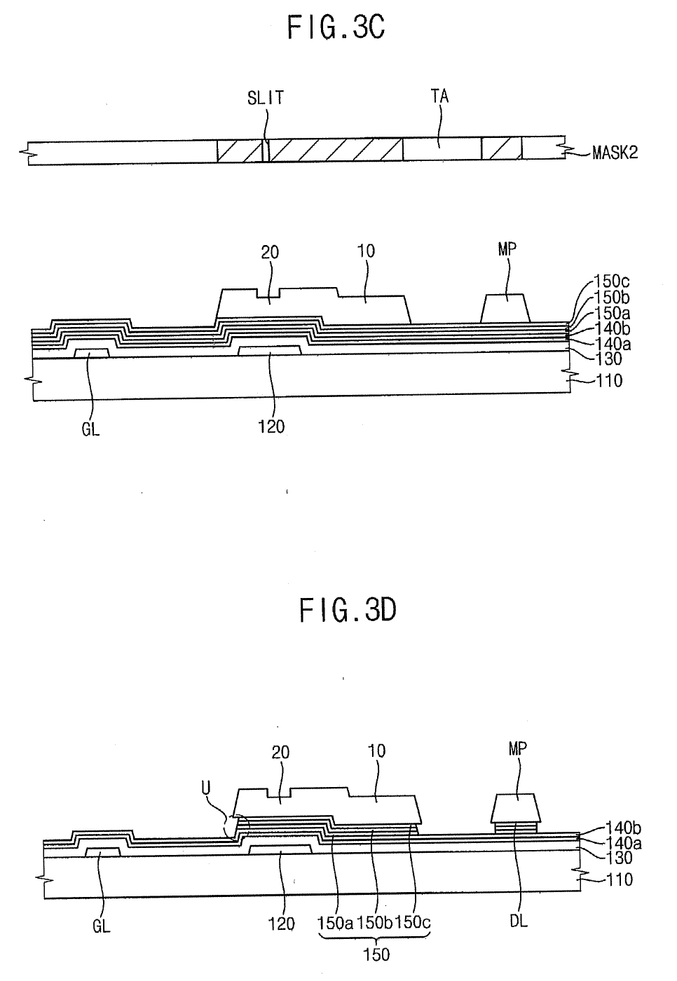

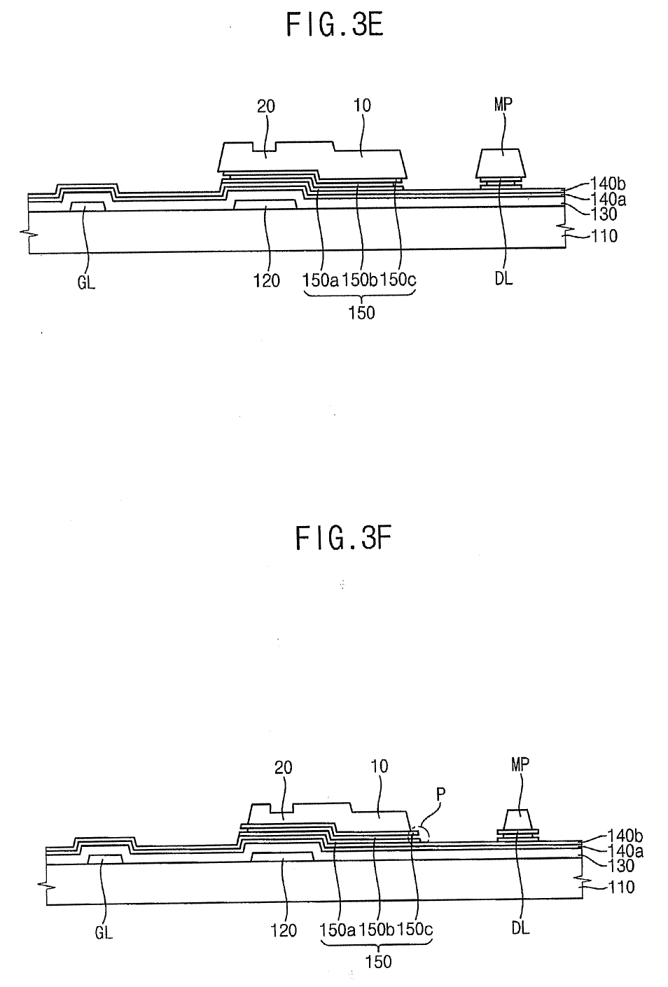

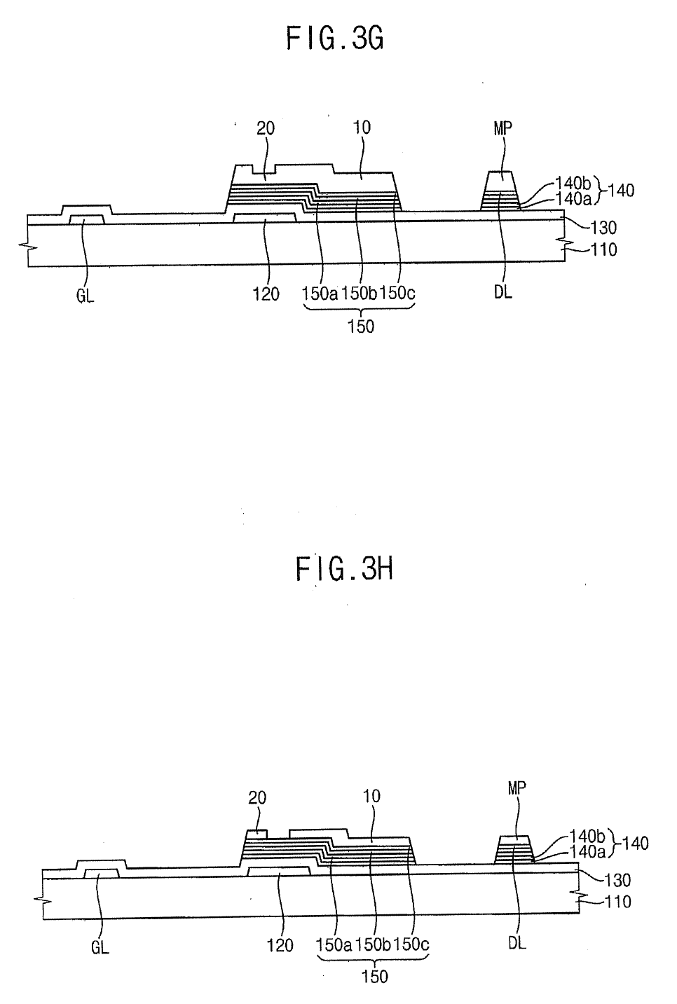

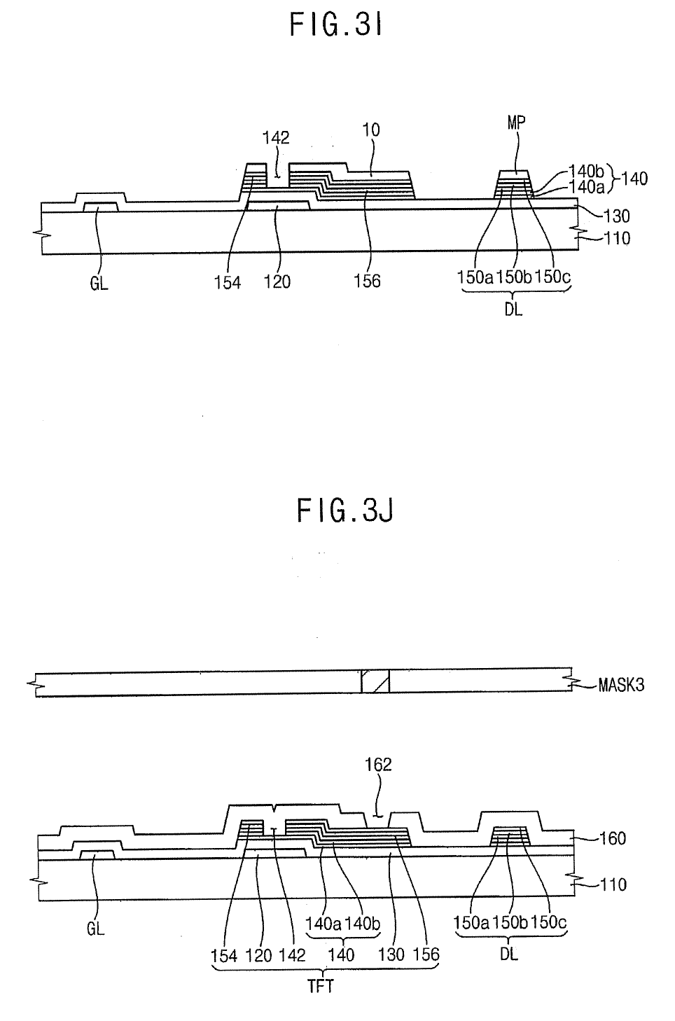

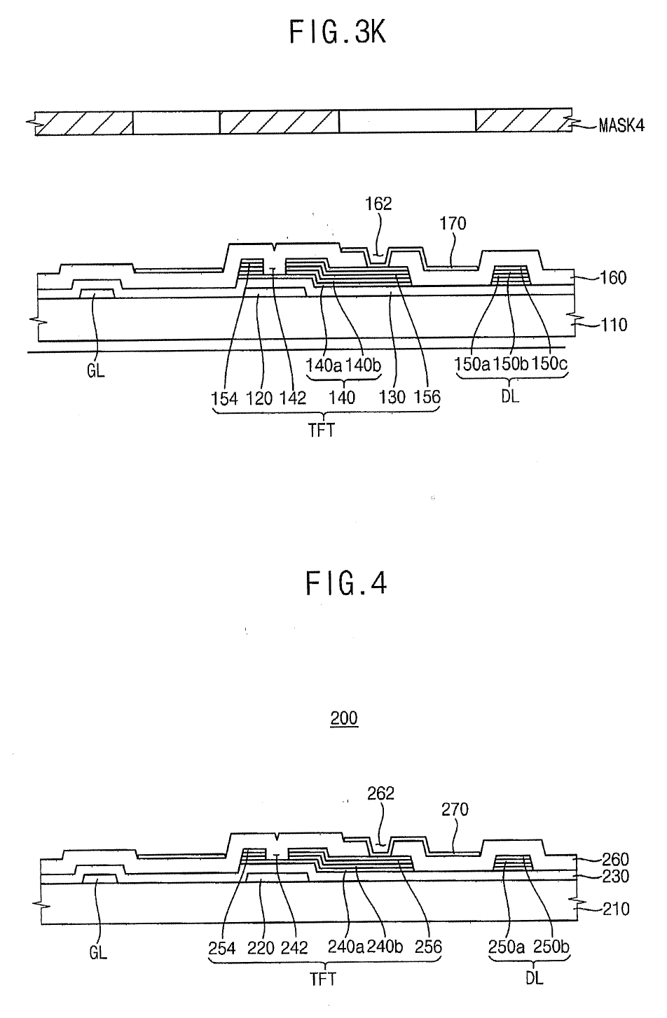

Hereinafter, an exemplary embodiment of a method of manufacturing a display substrate will be described in more detail with reference to FIGS. 1, 2 and 3A to 3K. FIGS. 3A to 3K are cross-sectional views illustrating an exemplary embodiment of a method of manufacturing the display substrate shown in FIG. 2.

Referring to FIGS. 1 and 3A, a metal layer (not shown) is formed on the base substrate 110. The metal layer is etched through a photolithography process using a first mask MASK1 to form the first metal pattern including the gate lines GL, the gate electrode 120 and the storage common lines STL.

Examples of the metal which may be used for the metal layer include chromium, aluminum, tantalum, molybdenum, titanium, tungsten, copper, silver, etc. These may be used alone, in an alloy thereof or in a combination thereof. Alternatively, the metal layer may have a multi-layered structure including a plurality of layers.

Referring to FIG. 3B, the gate insulating layer 130, the active layer 140a and the ohmic contact layer 140b are formed on the base substrate 110 having the first metal pattern, in sequence, through a plasma enhanced chemical vapor deposition (“PECVD”) process. The gate insulating layer 130 includes silicon nitride. The active layer 140a includes amorphous silicon (“a-Si:H”). The ohmic contact layer 140b includes n+ amorphous silicon. The n+ impurities may be implanted into the upper portion of the amorphous silicon layer to form the ohmic contact layer 140b.

The first metal layer 150a, the second metal layer 150b and the third metal layer 150c are sequentially formed on the ohmic contact layer 140b. The first metal layer 150a includes molybdenum or molybdenum alloy. The second metal layer 150b includes aluminum or aluminum alloy. The third metal layer 150c includes molybdenum or molybdenum alloy. For example, the first, second and third metal layers 150a, 150b and 150c may be formed through a sputtering method.

Referring to FIGS. 1 and 3C, a photoresist film (not shown) is coated on the third metal layer 150c. The photoresist film is exposed through a second mask MASK2 having a slit SLIT. The second mask MASK2 may further include a plurality of slits. When the second mask MASK2 includes the slit SLIT, a positive photoresist may be more easily patterned compared to a negative photoresist. In FIG. 3C, the photoresist film includes the positive photoresist.

About 100% of the light incident into an opening portion TA of the second mask MASK2 passes through the opening portion TA to be irradiated onto the photoresist film (not shown). The light incident into the slit SLIT is scattered by the slit SLIT so that a portion of the light incident into the slit SLIT is irradiated onto the photoresist film. When the photoresist film is developed, the exposed portion of the photoresist film is removed by a developing agent, and an unexposed portion of the photoresist film remains intact forming a photoresist pattern MP.

A thickness of the photoresist pattern MP corresponding to the slit SLIT, which is partially exposed, is less than a thickness of the photoresist pattern MP corresponding to the unexposed portion.

Therefore, the unexposed portion of the photoresist pattern MP forms the first patterned portion 10, and the photoresist pattern MP corresponding to the slit SLIT forms the second patterned portion 20.

The first patterned portion 10 corresponds to the source lines DL, the source electrode of the switching element TFT and the drain electrode of the switching element TFT. The second patterned portion 20 corresponds to the channel portion 142 (see FIG. 2) of the switching element TFT.

Referring to FIG. 3D, the first, second and third metal layers 150a, 150b and 150c, respectively, are wet etched using the photoresist pattern MP as an etching mask to form the second metal pattern including an electrode pattern 150 and the source lines DL.

The wet etching process using an etchant includes isotropic etching. Thus, a portion of the first, second and third metal layers 150a, 150b and 150c under the photoresist pattern MP is partially etched to form an undercut U, as illustrated in FIG. 3D. Therefore, a side of the photoresist pattern MP protrudes with respect to a side of the first, second and third metal layers 150a, 150b and 150c by the wet etching process. In other words, a side of the first, second and third metal layers 150a, 150b and 150c is recessed (see undercut U in FIG. 3D) relative to a side of the photoresist pattern MP.

Referring to FIG. 3E, the second metal pattern is cleaned by a cleaning liquid which has an etching selectivity against aluminum. For example, the base substrate 110 having the second metal pattern may be dipped into a bath having the cleaning liquid for a predetermined time period. Alternatively, the cleaning liquid may be sprayed on the base substrate 110.

Examples of the cleaning liquid which may be used to clean the base substrate 110 and to selectively etch aluminum include hydrofluoric acid (HF), tetramethyl ammonium hydroxide (TMAH), but is not limited thereto. These may be used alone or in a combination thereof. For example, the cleaning liquid may include a solution of hydrofluoric acid of about 0.01% to about 10%, or a solution of tetramethyl ammonium hydroxide of about 0.01% to about 10%. Alternatively, the cleaning liquid may include hydrofluoric acid of about 0.1% to about 1.0%. The base substrate 110 including the second metal pattern may be cleaned for a time period of about sixty seconds to about two hundred seconds.

The cleaning liquid has the high etching selectivity against aluminum so that a side of the second metal layer 150b, formed of aluminum or aluminum alloy, is partially etched. For example, the second metal layer 150b is selectively etched so that the second metal layer 150b is recessed with respect to the first and third metal layers 150a and 150c by a predetermined distance. When the second metal layer 150b is recessed with respect to the first and third metal layers 150a and 150c, a protruding portion of the first and third metal layers 150a and 150c protects the second metal layer 150b from being etched by a chlorine based gas used in a dry etching process for partially etching the channel layer 140. When chlorine molecules of the chlorine based gas remains on a surface of the second metal layer 150b, the chlorine molecules may react with moisture in the air to form hydrochloric acid (HCl), thereby eroding the second metal layer 150b. However, in FIG. 3E, the second metal layer 150b is recessed with respect to the first and third metal layers 150a and 150c so that a decreased amount of the chlorine based gas makes contact with the second metal layer 150b, thereby preventing the second metal layer 150b from being eroded.

In addition, when the channel layer 140 is etched, the first and third metal layers 150a and 150c are also partially etched by the etchant for etching the channel layer 140. Thus, the recessed portion of the second metal layer 150b compensates for the etching amount of the first and third metal layers 150a and 150c such that the second metal layer 150b does not protrude beyond the first and third metal layers 150a and 150c after the etching process for etching the channel layer 140. When the second metal layer 150b protrudes with respect to the first and third metal layers 150a and 150c, the channel layer 140 which may be etched using the electrode pattern 150 as an etching mask may be also protrude with respect to the first and third metal layers 150a and 150c. However, in FIG. 3E, the second metal layer 150b is partially etched by the cleaning liquid so that a profile of a side of the electrode pattern 150 is improved, thereby preventing the channel layer 140 from protruding with respect to the first and third metal layers 150a and 150c.

For example, the cleaning process recesses the second metal layer 150b with respect to the first and third metal layers 150a and 150c by about 0.01 μm to about 2.0 μm. The cleaned base substrate 110 cleaned by the cleaning liquid is rinsed by deionized water.

Referring to FIG. 3F, a portion of the photoresist pattern MP protruding with respect to the second metal pattern is removed through a first ashing process using oxygen plasma. Thus, a thickness of the photoresist pattern MP is decreased, and a side portion of the photoreist pattern MP is partially removed. Therefore, the protruding portion of the photoresist pattern MP, which protrudes with respect to the second metal pattern, is removed, and the photoresist pattern MP may be recessed with respect to the first and third metal layers 150a and 150c. For example, the photoresist pattern MP may have substantially the same width as that of the second metal layer 150b. Thus, the first and third metal layers 150a and 150c have a protrusion P which protrudes with respect to the photoresist pattern MP and the second metal layer 150b.

Referring to FIG. 3G, the second metal pattern and the channel layer 140 are dry etched using the photoresist pattern MP which is ashed by the first ashing process, in sequence. In FIGS. 3F and 3G, the protrusion P of the first and third metal layers 150a and 150c, which protrudes with respect to the photoresist pattern MP and the second metal layer 150b, is removed.

In addition, the dry etched channel layer 140 remains under the second metal pattern, and corresponds to the second metal pattern. For example, the side of the channel layer 140 may protrude with respect to the side of the dry etched second metal pattern at a distance of no more than about 0.5 μm. Thus, the channel layer 140 is patterned to have substantially the same etching surface as the second metal pattern.

The protrusion P of the first and third metal layers 150a and 150c are etched by using a gas mixture including a sulfur hexafluoride gas and an oxygen gas or a gas mixture including a chlorine gas and an oxygen gas, for example, but is not limited thereto.

Alternatively, examples of an etching gas which may be used for etching the channel layer 140 may include sulfur hexafluoride gas, chlorine gas, tetrafluoromethane gas, hydrochloric acid gas, etc. These may be used alone or in a combination thereof. The chlorine based gas such as the chlorine gas or the hydrochloric acid gas may remain on the surface of the second metal layer 150b to erode a portion of the second metal layer 150b. Thus, an amount of the chlorine based gas may be decreased during the dry etching process for etching the protrusion P of the first and third metal layers 150a and 150c and the channel layer 140.

Referring to FIG. 3H, the photoresist pattern MP is ashed through a second ashing process using oxygen plasma to decrease a thickness of the photoresist pattern MP. In FIGS. 3G and 3H, the second patterned portion 20 which has a smaller thickness than the first patterned portion 10 is removed, and the thickness of the first patterned portion 10 is decreased. When the second patterned portion 20 is removed, the third metal layer 150c of the electrode pattern 150 corresponding to the second patterned portion 20 is exposed.

Referring to FIGS. 3H and 3I, the electrode pattern 150 is partially etched by using the first patterned portion 10 as an etching mask. When the electrode pattern 150 is wet etched, the electrode pattern 150 may be more etched than the channel layer 140 to form a skew so that the channel layer 140 may be protruded with respect to the source electrode 154 and the drain electrode 156. In FIGS. 3H and 3I, the electrode pattern 150 may be dry etched. Thus, the source electrode 154 and the drain electrode 156 spaced apart from the source electrode 154 are formed. Alternatively, the electrode pattern 150 may also be wet etched to form the source electrode 154 and the drain electrode 156.

The ohmic contact layer 140b is dry etched using the first patterned portion 10, the source electrode 154 and the drain electrode 156 as an etching mask to expose a portion of the active layer 140a interposed between the source electrode 154 and the drain electrode 156. Thus, the channel portion 142 is formed between the source electrode 154 and the drain electrode 156.

The first patterned portion 10 which remains on the source electrode 154 and the drain electrode 156 is removed through an ashing process using oxygen plasma.

Referring to FIG. 3J, the passivation layer 160 is formed on the gate insulating layer 130 on which the second metal pattern is formed. The passivation layer 160 is partially etched through a photolithography process using a third mask MASK3 to form a contact hole 162 through which the drain electrode 156 is partially exposed.

Referring to FIG. 3K, a transparent conductive layer is deposited on the passivation layer 160 having the contact hole 162. Examples of a transparent conductive material which may be used for the transparent conductive layer include indium tin oxide, indium zinc oxide, but is not limited to the foregoing. The transparent conductive layer is patterned through a photolithography process using a fourth mask MASK4. Thus, the pixel electrode 170 electrically connected to the drain electrode 156 through the contact hole 162 is formed, as illustrated in FIG. 3K.

In FIGS. 3J to 3K, the contact hole 162 of the passivation layer 160 is formed using the third mask MASK3, and the pixel electrode 170 is formed using the fourth mask MASK4 such that the display substrate 100 is formed using four masks (e.g., MASK 1, MASK 2, MASK 3 and MASK 4). Alternatively, the passivation layer 160 and the pixel electrode 170 may be patterned using one mask such that the display substrate 100 may be formed by using three masks (e.g., MASK 1, MASK 2 and MASK 3/4).

FIG. 4 is a cross-sectional view illustrating a display substrate in accordance with another exemplary embodiment of the present invention.

Referring to FIG. 4, the display substrate 200 includes a second metal pattern including a source line DL, a source electrode 254 and a drain electrode 256. Alternatively, the second metal pattern may further include a plurality of source lines, a plurality of source electrodes and a plurality of drain electrodes. The second metal pattern may have a double layered structure including a first metal layer 250a and a second metal layer 250b. Examples of metal which may be used for the first metal layer 250a include aluminum, aluminum alloy, but is not limited thereto. Examples of metal which may be used for the second metal layer 250b include molybdenum, molybdenum alloy, but is not limited thereto. The display substrate 200 of FIG. 4 is the same as the display substrate 100 shown in FIG. 2 except for the second metal pattern. Thus, any further explanation concerning the above elements will be omitted.

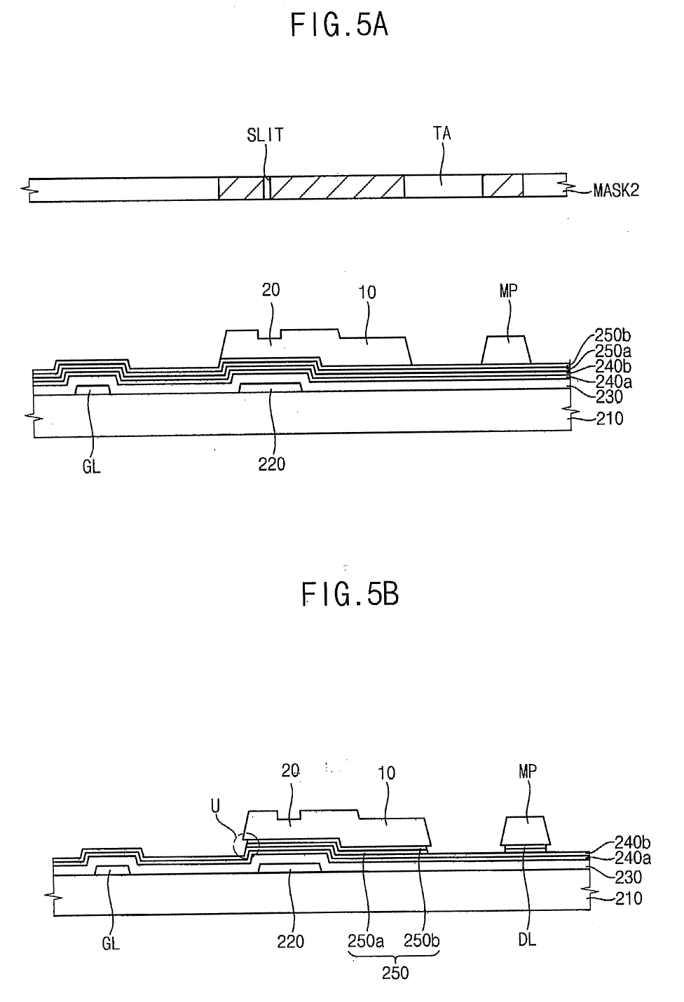

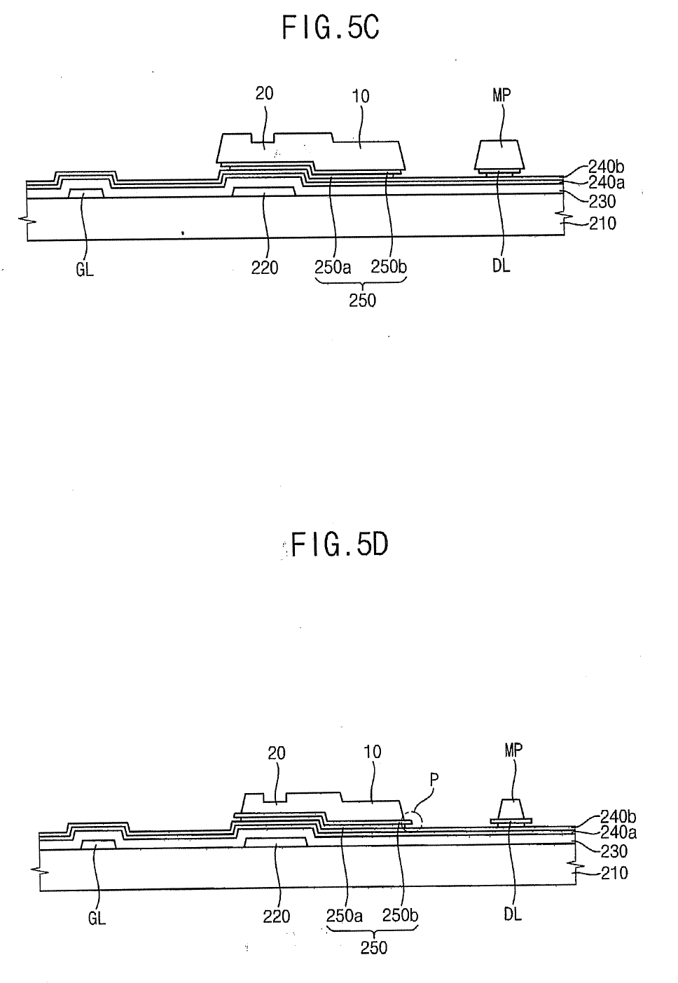

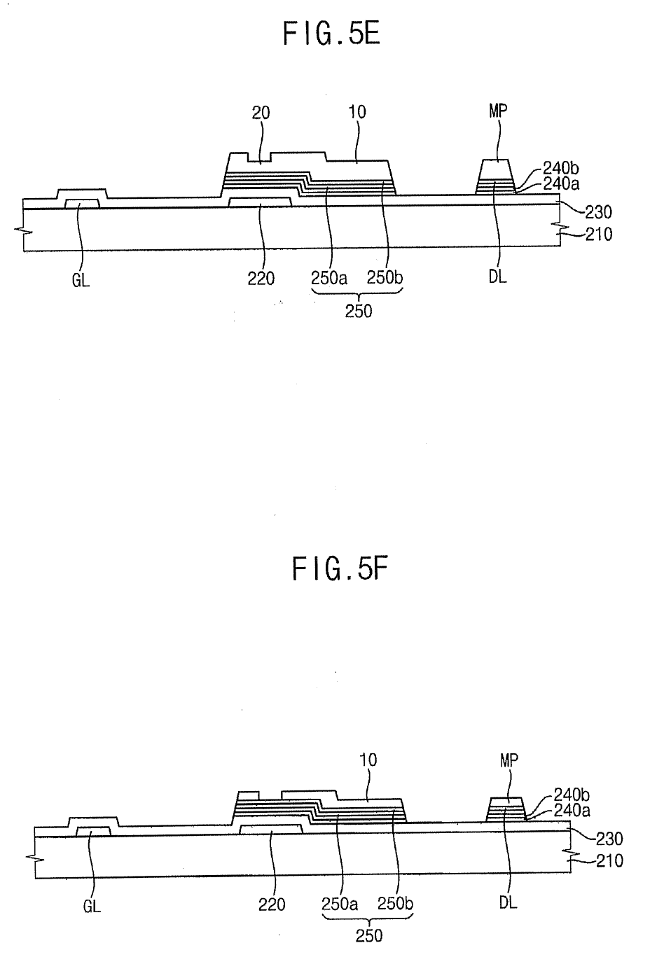

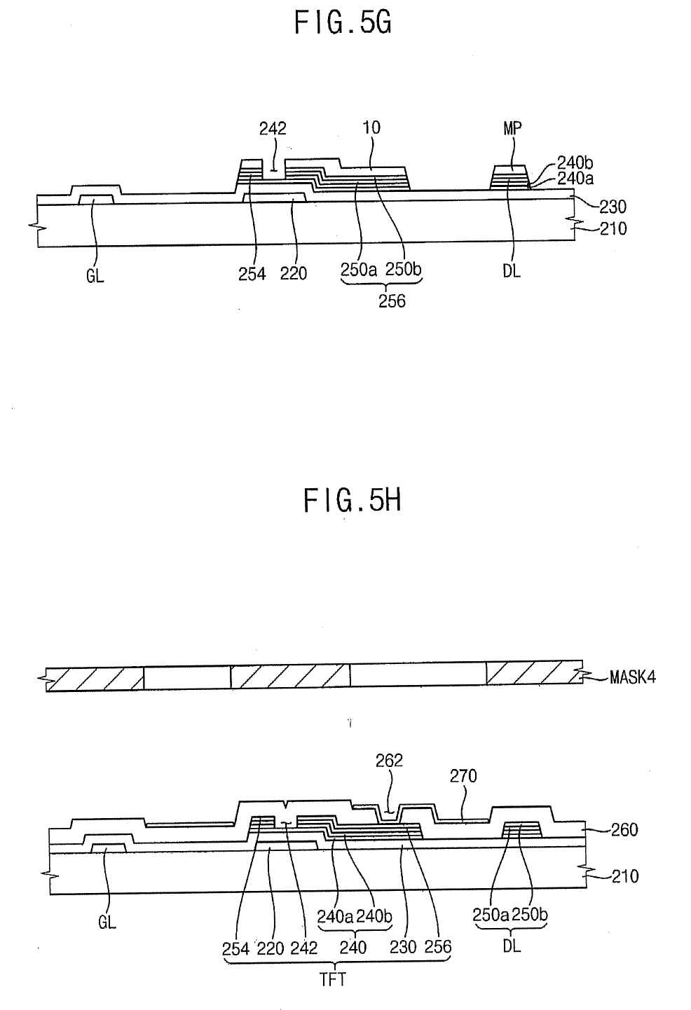

FIGS. 5A to 5H are cross-sectional views illustrating a method of manufacturing the exemplary display substrate shown in FIG. 4.

Referring to FIG. 5A, a metal layer (not shown) is formed on a base substrate 210. The metal layer is etched through a photolithography process using a first mask (not shown) to form a first metal pattern including a plurality of gate lines GL, a plurality of gate electrodes 220 (only one shown) and a plurality of storage common lines STL (see FIG. 1). The first metal pattern of FIG. 5A is the same as in FIG. 3A. Thus, any further explanation concerning the above elements will be omitted.

A gate insulating layer 230, an active layer 240a and an ohmic contact layer 240b are sequentially formed on the base substrate 210 having the first metal pattern through a plasma enhanced chemical vapor deposition (“PECVD”) process. The gate insulating layer 230 may include silicon nitride. The active layer 240a may include amorphous silicon (a-Si:H). The ohmic contact layer 240b may include n+ amorphous silicon. An upper portion of an amorphous silicon layer may include n+ impurities implanted therein to form the ohmic contact layer 240b.

The first metal layer 250a and the second metal layer 250b are sequentially formed on the ohmic contact layer 240b. The first metal layer 250a may include aluminum or aluminum alloy. The second metal layer 250b may include molybdenum or molybdenum alloy.

A photoresist film (not shown) is coated on the second metal layer 250b. The photoresist film is exposed through a second mask MASK2 having a slit SLIT. The second mask MASK2 may further include a plurality of slits (not shown). When the photoresist film is developed, the exposed portion of the photoresist film is removed by a developing agent, and an unexposed portion of the photoresist film remains to form a photoresist pattern MP.

A thickness of the photoresist pattern MP corresponding to the slit SLIT, which is partially exposed, is less than a thickness of the photoresist pattern MP corresponding to the unexposed portion.

Therefore, the unexposed portion of the photoresist pattern MP forms a first patterned portion 10, and the photoresist pattern MP corresponding to the slit SLIT forms the second patterned portion 20. The first patterned portion 10 corresponds to the source lines DL, the source electrode of a switching element TFT and the drain electrode of the switching element TFT. The second patterned portion 20 corresponds to the channel portion 142 (see FIG. 2) of the switching element TFT.

Referring to FIG. 5B, the first and second metal layers 250a and 250b are wet etched using the photoresist pattern MP as an etching mask to form the second metal pattern including an electrode pattern 250 and the source lines DL.

The wet etching process using an etchant includes isotropic etching. Thus, a portion of the first and second metal layers 150a and 150b under the photoresist pattern MP is partially etched to form an undercut U, as illustrated in FIG. 5B. Therefore, a side of the photoresist pattern MP protrudes with respect to a side of the first and second metal layers 250a and 250b as a result of the wet etching process.

Referring to FIG. 5C, the second metal pattern is cleaned using a cleaning liquid which has an etching selectivity against aluminum. For example, the base substrate having the second metal pattern may be dipped into a bath having the cleaning liquid for a predetermined time period. Alternatively, the cleaning liquid may be sprayed on the base substrate 210. The cleaning liquid of FIG. 5C is substantially the same as that described above in FIG. 3C. Thus, any further explanation concerning the above elements will be omitted.

The cleaning liquid has the high etching selectivity against aluminum so that a side of the first metal layer 250a formed of aluminum or aluminum alloy is partially etched. For example, the first metal layer 250a is selectively etched so that the first metal layer 250a is recessed with respect to the second metal layer 250b by a predetermined distance. When the first metal layer 250a is recessed with respect to the second metal layer 250b, a protruding portion of the second metal layer 250b protects the first metal layer 250a from being etched by a chlorine based gas used in a dry etching process for partially etching the channel layer 240. In FIG. 5C, the first metal layer 250a is recessed with respect to the second metal layer 250b such that an amount of the chlorine based gas which makes contact with the first metal layer 250a is decreased, thereby preventing the first metal layer 250a from being eroded. Thus, a protrusion of the channel layer 140 with respect to the second metal layer 250b is prevented.

For example, the first metal layer 250a is recessed with respect to the second metal layer 150b by about 0.01 μm to about 2.0 μm as a result of the cleaning process. The cleaned base substrate 210 cleaned by the cleaning liquid is rinsed by deionized water.

Referring to FIG. 5D, a portion of the photoresist pattern MP protruding with respect to the second metal layer 250b of the second metal pattern is removed through a first ashing process using oxygen plasma. Thus, a thickness of the photoresist pattern MP is decreased, and a side portion of the photoreist pattern MP is partially removed. Therefore, the protruding portion of the photoresist pattern MP which protrudes with respect to the second metal layer 250b is removed, and the photoresist pattern MP may be recessed with respect to the second metal layer 250b. For example, the photoresist pattern MP may have substantially the same width as the first metal layer 250a. Thus, the second metal layer 250b has a protrusion P which protrudes with respect to the photoresist pattern MP and the first metal layer 250a.

Referring to FIG. 5E, the protrusion P of the second metal pattern and the channel layer 240 are dry etched using the photoresist pattern MP which is ashed by the first ashing process, in sequence. In FIG. 5E, the protrusion P which protrudes with respect to the first metal layer 250a is removed. In addition, the dry etched channel layer 240 remains under the second metal pattern. For example, the side of the channel layer 240 may protrude with respect to the side of the dry etched second metal pattern at a distance of no more than about 0.5 μm. Thus, the channel layer 240 is patterned to have substantially the same etching surface as that of the second metal pattern.

The protrusion P of the second metal layer 250b is etched using a gas mixture including a sulfur hexafluoride gas and an oxygen gas or a gas mixture including a chlorine gas and an oxygen gas. Alternatively, examples of an etching gas which may be used for etching the channel layer 240 may include sulfur hexafluoride gas, chlorine gas, tetrafluoromethane gas, hydrochloric acid gas, but is not limited thereto. These may be used alone or in a combination thereof.

The chlorine based gas, such as the chlorine gas or the hydrochloric acid gas, may remain on the surface of the first metal layer 250a to erode a portion of the first metal layer 250a. Thus, an amount of the chlorine based gas may be decreased during the dry etching process for etching the protrusion P of the second metal layer 250b and the channel layer 240.

Referring to FIG. 5F, the photoresist pattern MP is ashed through a second ashing process using oxygen plasma so that a thickness of the photoresist pattern MP is decreased. In FIG. 5F, the second patterned portion 20 which has a smaller thickness than the first patterned portion 10 is removed, and the thickness of the first patterned portion 10 is decreased. When the second patterned portion 20 is removed, the second metal layer 250b of the electrode pattern 250 corresponding to the second patterned portion 20 is exposed.

Referring to FIG. 5G, the electrode pattern 250 is partially etched using the first patterned portion 10 as an etching mask. When the electrode pattern 250 is wet etched, the electrode pattern 250 may be more etched than the channel layer 240 to form a skew so that the channel layer 240 may be protruded with respect to the source electrode 254 and the drain electrode 256. In FIG. 5G, the electrode pattern 250 may be dry etched. Thus, the source electrode 254 and the drain electrode 256 spaced apart from the source electrode 254 are formed. Alternatively, the electrode pattern 250 may also be wet etched to form the source electrode 254 and the drain electrode 256.

The ohmic contact layer 240b is dry etched using the first patterned portion 10, the source electrode 254 and the drain electrode 256 as an etching mask to expose a portion of the active layer 240a interposed between the source electrode 254 and the drain electrode 256. Thus, the channel portion 242 is formed between the source electrode 254 and the drain electrode 256. The first patterned portion 10 which remains on the source electrode 254 and the drain electrode 256 is removed through an ashing process using oxygen plasma.

Referring to FIG. 5H, the passivation layer 260 is formed on the gate insulating layer 230 on which the second metal pattern is formed. The passivation layer 260 is partially etched through a photolithography process using a third mask (not shown) to form a contact hole 262 through which the drain electrode 256 is partially exposed.

A transparent conductive layer is deposited on the passivation layer 260 having the contact hole 262. Examples of a transparent conductive material which may be used for the transparent conductive layer include indium tin oxide, indium zinc oxide, but is not limited thereto. The transparent conductive layer is patterned through a photolithography process using a fourth mask MASK4. Thus, the pixel electrode 270 electrically connected to the drain electrode 256 through the contact hole 262 is formed.

In FIGS. 5A to 5H, the second metal pattern includes the first metal layer 250a and the second metal layer 250b on the first metal layer 250a. Alternatively, the first metal layer 250a may be on the second metal layer 250b. When the first metal layer 250a is formed on the second metal layer 250b, the second metal pattern may be formed through substantially the same method as the method shown in FIGS. 5A to 5H.

According to the present invention, the display substrate is manufactured through the following method. A source metal pattern including a first metal layer including molybdenum and a second metal layer including aluminum is formed on the channel layer. The source metal pattern is cleaned using the cleaning liquid having the etching selectivity against aluminum so that the second metal layer is recessed. The protruding first metal layer which protrudes as a result of the recession of the second metal layer is partially etched. The channel layer is etched using the source metal pattern as the etching mask. Thus, the source metal pattern and the channel layer are patterned to have substantially the same etching surface. Therefore, the protrusion of the channel portion is prevented thereby decreasing the leakage current inducted by the light and the afterimage. In addition, the second metal layer is selectively recessed so that a surface area of the second metal layer, which makes direct contact with the chlorine based gas used to etch the channel layer, is decreased, thereby decreasing an amount of the erosion of the second metal layer.

The present invention has been described with reference to the exemplary embodiments. It is evident, however, that many alternative modifications and variations will be apparent to those having skill in the art in light of the foregoing description. Accordingly, the present invention embraces all such alternative modifications and variations as falling within the spirit and scope of the appended claims.

What is claimed is:

1. A display substrate comprising:
a base substrate;
a first metal pattern formed on the base substrate, the first metal pattern including a gate line and a gate electrode of a switching element;
a gate insulating layer on the base substrate including the first metal pattern;
a second metal pattern on the gate insulating layer, the second metal pattern including a source electrode, a drain electrode and a source line;
a channel layer under the second metal pattern, the channel layer having substantially a same side surface as a side surface of the second metal pattern; and
a pixel electrode electrically connected to the drain electrode.

2. The display substrate of claim 1, wherein the second metal pattern comprises:
a first metal layer including molybdenum or molybdenum alloy; and
a second metal layer including aluminum or aluminum alloy.

3. The display substrate of claim 2, wherein the channel layer protrudes from the side surface of the second metal pattern by about 0.5 μm.

4. The display substrate of claim 3, wherein the channel layer comprises an active layer and an ohmic contact layer.

5. A method of manufacturing a display substrate, the method comprising:
forming a source metal layer including a first metal layer and a second metal layer on a base substrate, on which a first metal pattern including a gate line and a gate electrode, a gate insulating layer and a channel layer are formed in sequence;
etching the source metal layer using a photoresist pattern to form a second metal pattern including an electrode pattern and a source line;
cleaning the second metal pattern using a cleaning liquid which selectively etches the second metal layer to etch a side surface of the second metal layer by a predetermined amount;
ashing the photoresist pattern by a predetermined amount so that the photoresist pattern has substantially a same width as a width of the second metal layer;
dry etching a portion of the first metal layer and the channel layer using the photoresist pattern, the portion of the first metal layer and the channel layer protruding with respect to the second metal layer;
partially etching the electrode pattern to form a switching element including a source electrode, a drain electrode and a channel portion;
forming a passivation layer on the base substrate having the switching element; and
forming a pixel electrode electrically connected to the drain electrode.

6. The method of claim 5, wherein the first metal layer comprises molybdenum or molybdenum alloy.

7. The method of claim 6, wherein the second metal layer comprises aluminum or aluminum alloy.

8. The method of claim 7, wherein the cleaning liquid comprises a solution of hydrofluoric acid of about 0.01% to about 10%.

9. The method of claim 7, wherein the cleaning liquid comprises a solution of tetramethyl ammonium hydroxide of about 0.01% to about 10%.

10. The method of claim 7, wherein the first metal layer is formed on an upper surface of the second metal layer.

11. The method of claim 7, wherein the first metal layer is formed on a lower surface of the second metal layer.

12. The method of claim 5, wherein etching the side surface of the second metal layer further comprises etching the side surface of the second metal layer so that the second metal layer is recessed by about 0.01 μm to about 2.0 μm with respect to a side surface of the first metal layer.

13. The method of claim 12, wherein the dry etching the portion of the first metal layer and the channel layer using the photoresist pattern further comprises dry etching the portion of the first metal layer and the channel layer so that the first metal layer and the channel layer have substantially a same side surface as the second metal layer.

14. The method of claim 12, wherein side surfaces of the dry etched first metal layer and the dry etched channel layer protrude from the side surface of the second metal layer by a distance of no more than about 0.5 μm.

15. The method of claim 14, wherein the channel layer comprises an active layer and an ohmic contact layer formed on the active layer.

16. The method of claim 5, wherein the electrode pattern is partially etched through a dry etching process.

17. A method of manufacturing a display substrate, the method comprising:
forming a gate insulating layer, an active layer, an ohmic contact layer and a source metal layer including a first metal layer and a second metal layer on a base substrate on which a first metal pattern including a gate line and a gate electrode is formed;
patterning the source metal layer using a photoresist pattern to form a second metal pattern including an electrode pattern and a source line;
cleaning the second metal pattern by using a cleaning liquid that selectively etches the second metal layer;
removing the photoresist pattern so that the photoresist pattern has substantially a same width as a width of the second metal layer;
dry etching a portion of the first metal layer, the active layer and the ohmic contact layer using the photoresist pattern;
removing a predetermined thickness of the photoresist pattern to expose a portion of the electrode pattern;
partially etching the exposed portion of the electrode pattern to form a source electrode and a drain electrode of the switching element;
etching the ohmic contact layer using the source and drain electrodes as an etching mask to expose a portion of the active layer;
forming a passivation layer partially exposing the drain electrode; and
forming a pixel electrode electrically connected to the drain electrode.

18. The method of claim 17, further comprising removing the photoresist pattern remaining on the source and drain electrodes.

19. The method of claim 17, wherein the cleaning the second metal pattern comprises cleaning the second metal pattern so that a side surface of the second metal layer is recessed with respect to a side surface of the first metal layer by about 0.01 μm to about 2.0 μm.

20. The method of claim 19, wherein the dry etching the portion of the first metal layer, the active layer and the ohmic contact layer using the photoresist pattern further comprises dry etching the portion of the first metal layer, the active layer and the ohmic contact layer so that the first metal layer, the active layer and the ohmic contact layer have substantially the same side surface as the side surface of the second metal layer.

21. The method of claim 19, wherein side surfaces of the dry etched active layer and the dry etched ohmic contact layer protrude from the side surface of the second metal layer by a distance of no more than about 0.5 μm.

22. The method of claim 17, wherein the electrode pattern is partially etched through a dry etching process.
